(19) United States
(12) Patent Application Publication
(10) Pub. No.: US 2010/0015358 A1
(43) Pub. Date: Jan. 21, 2010

(54) APPARATUS AND METHOD FOR SURFACE FINISHING OF METALS AND METALLOIDS, METAL OXIDES AND METALLOID OXIDES, AND METAL NITRIDES AND METALLOID NITRIDES

(75) Inventors: Mirko Cernak, Bratislava (SK); Peter Kus, Bratislava (SK); Anna Zahoranova, Ivanka Pri Dunaji (SK)

Correspondence Address: WOODCOCK WASHBURN LLP, CIRA CENTRE, 12TH FLOOR, 2929 ARCH STREET, PHILADELPHIA, PA, 19104-2891, US

(73) Assignee: FACULTY OF MATHEMATICS, PHYSICS AND INFORMATICS OF COMMENIUS UNIVERSITY

(21) Appl. No.: 12/517,729

(22) PCT Filed: Dec. 4, 2007
(86) PCT No.: PCT/SK07/50021

§ 371 Date: Sep. 15, 2009

(30) Foreign Application Priority Data
Dec. 5, 2006 (SK) PP 5108-2006

(51) Int. Cl. C23C 16/513; C23C 16/00; C23C 16/52; H05H 1/24

(52) U.S. Cl. 427/576; 118/723 R; 427/569

(57) ABSTRACT

The present invention relates to an apparatus for treatment of the surface of metals and metalloids, metal oxides and metalloid oxides, and metal nitrides and metalloid nitrides using the action of electric plasma. The invention disclosed herein includes at least one electrode system (1) consisting of electrode systems (2) and (3) situated inside of a dielectric body (4). The electrode systems (2) and (3), above which diffuse plasma is generated preferably at atmospheric pressure, are situated on the same side of the treated surface (5) and are energised by alternating or pulsed electrical voltage applied between them. The invention further relates to a method for treatment of the surface of metals and metalloids, metal oxides and metalloid oxides, and metal nitrides and metalloid nitrides using the action of electric plasma, consisting in treating such surfaces with diffuse plasma generated using the apparatus according to the invention, preferably at atmospheric pressure. Alternatively, the plasma-treated surfaces can be coated with a H₂O containing solution, exposed to gaseous environment, or brought into contact with other materials.

### TECHNICAL FIELD

The invention relates to an apparatus and a method for surface treatment of metals and metalloids, metal oxides and metalloid oxides, and metal nitrides and metalloid nitrides using electric plasma, preferably under atmospheric pressure, and subsequent surface finishing of such plasma-modified surfaces.

### BACKGROUND ART

Under normal conditions, the surfaces of metals and metalloids, being in contact with atmospheric air, are covered with natural oxides. Such layers of oxides, as well as the surfaces of metal oxide- and metalloid oxide-based ceramic materials, are often coated with layers of other organic and/or inorganic materials to improve the useful properties and to obtain new useful properties. For example, oxidised surfaces of aluminium, copper, tin, iron and nickel are coated with silane layers that bind to the surface OH groups via hydrogen bonds. For this purpose it is necessary to activate the surfaces of metal oxides and metalloids, i.e., to remove the surface layer of adsorbed hydrocarbons and to increase the surface concentration of surface OH groups. Likewise, it is necessary to increase the surface concentration of OH groups on the surface of metal oxides and metalloids to achieve a strong bond with the layers applied using the sol-gel method and other coating methods.

With certain vacuum technologies, such as in the preparation of thin layers of metals and metalloids as well as layers of metal and metalloid oxides and nitrides using the organic chemical vapour deposition (MOCVD) method, the thin layers formed contain undesirable carbon-based impurities that impair their electric conductivity and other properties. Oxide- and nitride-covered surfaces of metals and metalloids, as well as those of metal oxide- and metalloid oxide-based ceramic materials, are often polluted with organic materials such as oils used in aluminium and steel sheet rolling, or with coal-based impurities originating from the preparation of metal and metalloid oxide layers using the sol-gel method. Surfaces so polluted need to be cleaned, for example, for subsequent painting, lamination or other surface finishing, as well as for various applications, for example, in electronics.

The surfaces of numerous non-metallic and metallic materials are coated with layers of metals and metalloids, metal and metalloid oxides and nitrides to achieve other useful properties. For example, the surface of silicon is coated with a layer of Pt to prepare conductive electrodes and couplings. The surface of glass is covered with a layer of SnO₂ to create an electrically conductive layer, or with a layer of TiO₂ to achieve self-cleaning properties. Using the processes of anodisation, the surface of aluminium is covered with a thick layer of Al₂O₃ for anti-corrosion protection, while that of silicon is covered with a layer of SiNₓ in the manufacture of solar cells, etc. It is often necessary to treat the surface of such layers of metals and metalloids, metal and metalloid oxides and nitrides to improve their useful properties.

In many applications, such as soldering of conductive connections on the surface of copper conductors in electrical engineering, the oxide coating of metallic surfaces is undesirable and the oxides need to be removed, for example, by etching.

For the above-mentioned treatments of metal and metalloid surfaces, metal and metalloid oxide and nitride surfaces, as well as for their etching, toxic and aggressive chemicals are commonly used. For example, Takehara et al.: J. Biosci. Bioeng. Vol. 89, No. 3 (2000) 267-70, describe the cleaning of Al₂O₃ particle surface, for subsequent coating with biomolecules, using an aggressive solution of NaOH and toxic ozone. K. M. Portays et al. in the paper Surf. Interface Analysis 36 (2004) 1361-1366 and U.S. Pat. No. 6,881,491 clean the surface of Al₂O₃ to remove organic molecules using aggressive agents based on strong acids. As described in S. Tossatti et al.: Langmuir 18 (2002) 353748, to deposit a monolayer of organic molecules, the surface of TiO₂ was activated and cleaned in a hot solution of HCl/H₂SO₄.

It has been known to activate, clean, modify the properties, and etch the surfaces of metals and metalloids, metal and metalloid oxides, and metal and metalloid nitrides advantageously using the action of electric plasma. Plasma treatment enables achieving desired surface properties without using toxic and aggressive chemicals. As it is technically substantially simpler to generate appropriate electric plasma under reduced pressure, most of the known papers report using plasma generated at pressures substantially lower than the atmospheric pressure. For example, US patent application 20030096472 describes the cleaning of thin layers of Pt and Ru using O₂ plasma. US patent application 20040069654 describes chloriding of silver surface using plasma. U.S. Pat. No. 5,000,819 describes the etching of the metal oxide surface using plasma generated at low pressures. The cleaning of the surface of steel coated with a layer of oxides using plasma generated at low pressures is described, for example, in US patent applications 20060108034 and 20060054184, in M. Mantel and J. P. Wightman: Surface and Interface Analysis, Volume 21, Issue 9 (1994), pages 595-605, and the cleaning of aluminium surfaces at similar conditions is described in C. Dartevelle et al.: Surface and Coatings Technology 173 (2003) 249-258, B. R. Strohmeier: Aluminium 68 (1992) 892, and in P. Watkinsom et al.: 2003 ECI Conference on Heat Exchanger Fouling and Cleaning: Fundamentals and Applications, Santa Fe, N. Mex., USA, Paper No. 15. In Y. Hashimoto, M. Hamagaki: Electrical Engineering in Japan, 154 (2006) 1-7, plasma generated at low pressure in O₂ atmosphere was used to treat the surface of electrodes of indium and tin oxides to improve their properties for the use in solar cells. In M. Stevenson et al.: Surf. Interface Anal. 26, (1998) 1027-1034, the surface of TiO₂ was activated to be subsequently coated with a sol-gel layer of SiO₂ using plasma generated at low pressure in a mixture of air and water vapours. In J. L. Parker et al.: J. Phys. Chem. 93 (1989) 6121-6125, the surface of mica was activated using the action of plasma generated at low pressure in water vapours to increase the concentration of surface OH groups and subsequent silanisation. In V. S. Bessmertnyi et al.: Glass and Ceramics 58 (2001) 362-364, the surface of nickel with a layer of natural oxide was reduced using the action of plasma generated in H₂ under low pressure. In B. O. Aronsson et al.: Journal of Biomedical Materials Research, 35 (1997) 49-73, a Ti surface with a layer of oxide formed by anodic oxidation was cleaned from adsorbed hydrocarbon molecules under low pressure in Ar plasma. E. S. Braga et al.: Thin Solid Films 73 (1980) L5-L6 describes the etching of SnO₂ under low pressure in N₂+C₂H₂Cl₂ plasma. In O. K. Tan et al.: Sensor (2005) 1181-1183, the properties of a SnO₂ layer used in gas detectors were improved by plasma treatment under low pressure.

The disadvantage of the above-discussed surface treatments using plasma generated at reduced pressure is the need to conduct the treatment in vacuum chambers, which increases costs, requires skilled personnel, makes it impossible to treat materials in a continuous mode, and entails high cost of treating workpieces with large dimensions. Plasma treatment at low pressures is also slow, as—with respect to low concentration of active particles—it requires exposure times of several minutes.

To eliminate these deficiencies, apparatuses were developed that can be used for plasma treatment, cleaning and etching of the surface of metals and metalloids, metal and metalloid oxides and nitrides using plasma generated at atmospheric pressure. Most of them, as described for steel surface cleaning in R. Thyen et al.: Plasmas and Polymers 5 (2000) 91-102, for activation of the oxidised surface of chromium in E. G. Fiantu-Dinu et al.: Surface and Coating Technology 174 (2003) 553-558, for aluminium foil activation in 0. M. Plassmann and G. Schubert: TAPPI 2004 PLACE Conference, www.tappi.org/index.asp?pid=307168ch=4, and in 0. M. Plassmann, G. Schubert: “Shedding a New Light on Corona-Treated Alu-Foil” 2004 PLACE Conference, in H. K. Hwang et al.: Surface and Coatings Technology 177-178 (2004) 705-710, for MgO surface cleaning in Chang Heon Yi et al.: Surface and Coatings Technology 177-178 (2004) 711-715, for the cleaning of indium-titanium oxide and for the activation of copper surface in U.S. Pat. No. 5,445,682, use for plasma generation a volume barrier discharge, sometimes referred to as corona or quiet discharge, whereupon the material to be treated is inserted between two electrodes supplied with alternating electric voltage, so that in this solution, the flux lines of the alternating voltage-generated displacement current pass through the metal oxide surface under treatment. Plasma can thus be generated at atmospheric pressure substantially in any gas, including air and oxygen. A disadvantage of this solution is that when treating the surface of a dielectric material that is, at the same time, a dielectric barrier on the surface of discharge electrodes, the discharge characteristics and those of plasma so generated depend on the thickness of the material to be treated and, consequently, it is not possible to treat materials of arbitrary thickness. A further disadvantage of this solution consists in that the volume plasma power density is relatively low and, consequently, the required plasma exposure time is of the order of 10 to 100 seconds. Another disadvantage of such a solution is that an increase in the plasma power density leads to an undesirable plasma filamentation and dramatic increase in the plasma gas temperature, resulting in nonuniform treatment of metal oxide surfaces.

To increase the plasma power density and, consequently, to reduce the plasma exposure times without the mentioned nonuniform treatment and damages to the treated material surface, the plasma devices generating diffuse atmospheric-pressure plasmas without filamentation were designed. The devices are based on the use of the so-called atmospheric pressure glow discharge, and their uses for the cleaning of various surfaces are described, for example, for metal surface cleaning, in U.S. Pat. No. 5,938,854, WO 2005062338, J. R. Roth and Y. Ku: Plasma Science, 1995. IEEE Conference Record—Abstracts, p. 251 and in C. H. Yi: Surface and Coatings Technology 171 (2003) 237-240, 0. Goossens et al.: Surface and Coatings Technology 142-144 (2001) 474-481 and the etching of copper oxide in hydrogen plasma in Y. Sawada et al.: J. Phys. D: Appl. Phys. 29 (1996) 2539-2544. In these cases, similarly as in the above-discussed applications of dielectric barrier discharge, the treated material was placed directly between the electrodes, of which at least one was coated with a dielectric material. A disadvantage of such devices is that the helium-containing working gas is to be used for preventing the plasma filamentation and gas heating, i.e., to generate diffuse cold plasma. Helium has a stabilising effect making it possible to generate diffuse cold plasma, however, it is expensive and its use significantly increases the cost of plasma treatment.

Other apparatuses generating diffuse plasma at atmospheric pressure without undesirable filaments use the plasma-jet method. This method is described in detail, for example, in A. Schütze et al.: IEEE Trans. on Plasma Science 26 (1998) 1685 and in US patent application No. 20030047540. With the plasma-jet method, plasma is generated, for example, using barrier, RF, or microwave discharge and is blown out from the generation site by a gas flow of the velocity of several m/s against the treated surface not placed directly between the electrodes but rather at a distance of usually several mm to cm from the site where plasma was generated. The use of plasma so generated for copper surface etching is described in US patent application 20020134403, for the surface cleaning of galvanised steel sheet and aluminium in 20060037996, for the cleaning of Al₂O₃ layer-coated aluminium, for example, in L. Bárdo\check{s} and H. Baránková: Surface and Coatings Technology 133-134 (2000) 522-527, in T. Yamamoto et al.: IEEE Trans. on Industry Appl. 40 (2004) 1220-1225, in W. Polini, L. Sorrentino, Appl. Surf. Science 214 (2003) 232-242, and in US patent application No. 20040026385. The use of a plasma-jet device for steel surface treatment is described, for example, in M. C. Kim et al.: Surface and Coatings Technology 171 (2003) 31.2-316, for steel surface sterilisation in US patent application No. 20040026385, for tin surface activation in US patent application No. 20060156983, for silver oxide surface reduction in US patent application No. 20050016456, and for the reduction of various metal oxide surfaces in US patent application No. 20060042545.

A disadvantage of plasma-jet devices is that a helium- or argon-containing working gas is mostly to be used for preventing the plasma filamentation and gas heating, i.e., to generate diffuse cold plasma. Helium and argon have a stabilising effect making it possible to generate diffuse cold plasma, however, they are expensive and their use significantly increases the cost of plasma surface treatment. A further disadvantage is that to prevent the sparking and working gas heating, it is necessary to generate the plasma in a large volume of fast flowing working gas, which increases significantly the energy and working gas consumption. An additional disadvantage of the plasma jet devices is that the plasma is generated at a distance from the treated metal oxide surface greater than 1 mm. This fact, together with the necessary flow of working gas, result in recombination and decay of a significant portion of the plasma active species without their contact with the treated surface or in their escape with the exhaust gases, therefore only small portion of plasma active species hit the surface with no utilisation of the effects of UV radiation generated in the discharge, which results in a low energy efficiency of such devices. Yet another disadvantage, as discussed, for example, in A. P. Napatovich: Plasmas and Polymer 6 (2001) 1-14, is that the plasma power density is only of the order of 1 to 10 W/cm³, resulting in too long plasma exposure times of the order of 10 seconds. A further disadvantage of such devices is that that the plasma is usually not safe in an unintended contact with the human body.

### DISCLOSURE OF INVENTION

The disadvantages of the above-mentioned methods and devices are solved by the apparatus in accordance with the present invention, where the surface of metal or metalloid, the metal oxide- or metalloid oxide-coated surface, or the metal or metalloid nitride-coated surface is exposed to a thin layer non-equilibrium plasma, preferably with a thickness ranging from 0.05 mm to 1 mm. The plasma layer is generated on a portion of a dielectric body surface, advantageously the body made from a ceramics or glass, preferably on the dielectric body surface above the surfaces of conductive electrodes situated inside of the dielectric body. The plasma exposed surface is situated in a vicinity of the dielectric body surface on which the plasma layer is generated, preferably closer than 1 mm and farther than 0.05 mm, from the dielectric body surface on which the plasma layer is generated.

The plasma is generated in any working gas, preferably in the working gas not containing helium and containing molecules of N₂, O₂, H₂O, CO₂, and halohydrocarbon molecules. The plasma is generated at gas pressures ranging from 1 kPa to 1000 kPa, preferably at atmospheric pressure and, preferably, using working gas flow velocity less than 10 m/s.

The plasma layer is generated on the surface of a dielectric body, which is separating conductive electrodes situated inside of the dielectric body, in such a way that the electrodes surfaces are not in contact with the plasma. The electrodes are energised by an alternating or pulsed electrical voltage with a frequency ranging from 50 Hz to 1 GHz and a magnitude from 100 V to 100 kV. The minimum interelectrode distance is less than 2 mm and more than 0.05 mm.

The electrodes are situated in such a way that a significant portion of the electric field lines flux, which is larger than 50% of the total electric field lines flux flowing between the electrodes separated by a layer of the dielectric material and supplied with alternating electric voltage, is not intersecting the plasma-treated material surface.

It was found surprisingly that using the method in accordance with the invention, it is possible to generate, above the surface of conductive electrodes positioned in a dielectric material in the above-described manner, visually diffuse strongly nonequilibrium plasmas with high power densities reaching the order of 100 W/cm³ suitable for fast cleaning, activating, and etching of metal or metalloid surface, metal or metalloid oxide-coated surface, or metal or metalloid nitride-coated surface at exposure times of the order of 0.1 to 1 s. An advantage of the solution in accordance with the invention is that such diffuse plasma can be generated even without a high working gas flow and without using a helium- or argon-containing working gas. It was found surprisingly that the homogeneity of plasma so generated, as opposed to all known plasma devices tested previously for the above-mentioned purpose, increases with growing plasma power density.

Another surprising finding is that the plasma uniformity, diffusivity and power density is increased by situating the treated metal or metalloid surface, metal or metalloid oxide-coated surface, or metal or metalloid nitride-coated surface at a distance from 0.05 to 1 mm, preferably from 0.1 to 0.3 mm, from the dielectric body surface on which the plasma layer is generated. Another surprising finding is that plasma so generated is safe in contact with the surface of human body. Yet another surprising finding is that the exposure to the plasmas so generated at exposure times shorter than 10 seconds does not result in any roughening greater than 10 nm.

### BRIEF DESCRIPTION OF DRAWINGS

Examples of the electrode systems according to the invention are described schematically in the attached figures. The illustrations in the figures are confined to the planar electrode systems.

FIG. 1 is a schematic cross-sectional view illustrating an electrode system that can be part of the apparatus for the plasma treatment of metal or metalloid surface, or metal or metalloid oxide or nitride coated-surface without an auxiliary electrode. The treated substrate surface is situated at a distance of not more than 1 mm from the electrode system.

FIG. 2 shows a part of the apparatus for the plasma treatment of metal or metalloid surface, or metal or metalloid oxide or nitride coated surface with an auxiliary electrode.

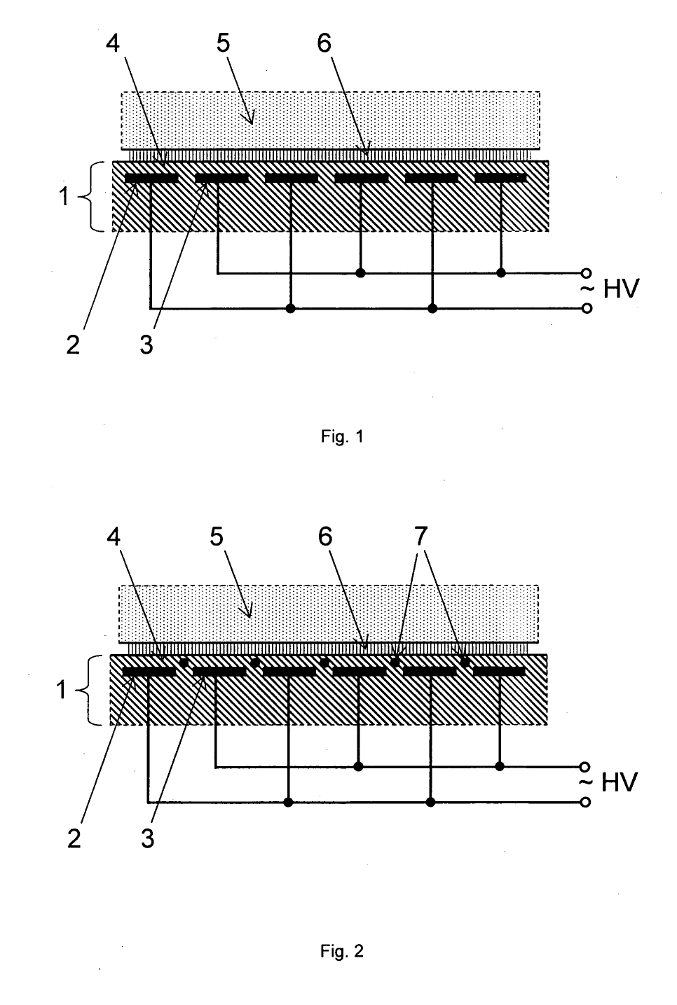

### MODES FOR CARRYING OUT THE INVENTION

### Example 1

The apparatus and method according to the present invention were used to hydrophilise the surface of aluminium, silver, and copper foil coated with a natural layer of oxides. The water wetting angles of such surfaces cleaned with ethanol were 88° for the Al foil, 67° for the Ag foil and 79° for the Cu foil. The foil surfaces situated at a distance of 0.7 mm from the surface of the electrode system were treated for 2 seconds using the method in accordance with the invention in atmospheric-pressure air plasma at a power density of 5 W/cm². The water wetting angles following the plasma treatment were 30° for the Al foil, 45° for the Ag foil and 32° for the Cu foil, improving thus their properties for subsequent surface treatments.

### Example 2

The surface of a heat-resistant FeCr (23%) Al (5%) foil with an addition of lanthanides coated with a layer of natural oxides was cleaned using acetone and, after drying, activated using the standard method of 3 minutes' treatment in a solution of 10% H₂SO₄+10 g/l HCl at the temperature of 70° C. and then thoroughly cleaned in distilled water by ultrasound. For comparison, the surface of a FeCrAl foil situated at a distance of 0.1 mm from the surface of the electrode system was treated for 2 seconds using the method in accordance with the invention in atmospheric-pressure air plasma at a power density of 5 W/cm². Subsequently, both surfaces were coated with a 5-micrometer thick SiO₂ layer prepared using the sol-gel method. The samples were tested using the thermal shock method well known in metallurgy by being 2000 times heated to the temperature of 1200° C. and subsequently cooled to room temperature. Examination using electron scanning microscopy revealed the formation of cracks on the interface of the SiO₂ layer and the foil activated using the standard method while that treated with plasma showed no cracks in the intermediate layer.

### Example 3

A micrometer-thick layer of MgO was coated on a glass substrate using magnetron sputtering. The layer so prepared was exposed to ambient air for 1 day. Subsequently, it was inserted in a vacuum chamber with the vacuum of 10⁻⁷ Torr equipped with quadrupole vacuometer and heated up to 600° C. Before placing in the vacuum chamber and subsequent heating to 600° C., an identical sample was treated using the method in accordance with the invention by a 5 second O₂ plasma exposure at a power density of 10 W/cm². The treated sample surface was situated at a distance of 0.3 mm from the electrode system. Plasma-treated sample showed an 8-times lower emission of water vapour after heating up and approximately twice the value of the secondary emission coefficient, showing thus an improvement of its properties for the use, for example, in the manufacture of plasma screens.

### Example 4

A 50 nm thick tantalum oxide was deposited on the surface of a wafer of

polycrystalline nitrided silicon using the CVD method from a mixture of Ta(OC₂H₅)₅ and O₂. The layer so prepared was treated using the method according to the present invention in O₂ plasma at a pressure of 0.3 bar and a power density of 10 W/cm². The treated sample surface was situated at a distance of 1.5 mm from the electrode system. The treatment removed the residues of C and H atoms in the deposited layer and significantly improved its dielectric properties. A low value of the residual current of the order of 10⁻⁷ A/cm² was reached at an electric field intensity of 1 MV/cm. Tantalum oxide layers so treated can be advantageously used in the manufacture of ultra thin capacitors.

### Example 5

A 600 nm thick layer of SnO₂+5% Sb was prepared on a glass surface using the sol-gel method at the sintering temperature of 450° C. and time of 10 min. The sample was then heated for 20 min at 350° C. in vacuum of the order of 10⁻⁴ Pa, achieving thus the value of specific resistance of 0.09×10⁻⁴ Ohm·m. The layer so prepared was treated using the method according to the present invention in H₂ plasma at a pressure of 0.3 bar and a power density of 10 W/cm². The treated sample surface was situated at a distance of 1 mm from the electrode system. The treatment resulted in a reduction of the sample's specific resistance to 0.06×10⁻⁴ Ohm·m.

### Example 6

1 mm thick samples of 96% Al₂O₃ ceramics were prepared using the green tape method. Samples were polished under running water using a 1200 grid SiC-coated paper and carefully cleaned using demineralised water in an ultrasound cleaner. Subsequently, the sample surface was activated using the method and apparatus according to the invention in ambient air at a power density of 5 W/cm² and sample distance of 0.25 mm from the surface of the electrode system. Samples were subsequently bonded by an epoxy resin and, after curing, cut using a low-speed diamond disc to the dimensions of 5 mm×5 mm to measure the strength of the adhesion. The bond strength was measured using the standard method on an Instron tensile testing machine at the jaw speed of 0.5 mm/min. The bond strength was determined as the proportion of the force and the bonded area. The value of the bond strength of plasma-unactivated samples of 1.8 MPa was substantially lower than the value of 9.8 MPa measured for plasma-treated samples.

### Example 7

A 60-nm thick TiO₂-coating was prepared on a glass substrate by standard magnetron sputtering method. A sample so prepared was treated using the method and apparatus according to the invention for 30 s in N₂+5% H₂ atmospheric pressure plasma at a power density of 10 W/cm² and sample distance of 0.3 mm from the surface of the electrodes. XPS analysis revealed the presence of N atoms in the surface layers with the relative concentration of several percent. This verified the possible use of the method and apparatus according to the invention for TiO₂ doping with N atoms to improve the photocatalytic effect of TiO₂ layers.

### Example 8

Glass samples coated with indium titanium oxide (ITO) supplied by Merck-Taiwan Corp. were cleaned by wiping with an ethanol-impregnated paper and subsequently cleaned with methanol and deionised water in an ultrasound cleaner. The water wetting angle of the samples so cleaned measured using the sitting drop method was 95°. Samples so cleaned were surface-treated using the method and apparatus according to the invention under a pressure of 0.3 bar in O₂ plasma at a power density of 10 W/cm², sample distance from the surface of the electrode system of 0.3 mm and exposure time of 3 s. After the treatment, the wetting angle dropped to 15°. At the same time, an increase of the work function by 0.2 eV was measured for the O₂ plasma-activated samples. Such plasma-treated samples with the above-mentioned properties can advantageously be used, for example, in the manufacture of organic light emitting diodes (OLED).

### Example 9

The surface of galvanised steel sheet was cleaned in a standard manner using 3% aqueous solution of alkaline cleaning agent NOVOMAX 187 U manufactured by Henkel. For comparison, the surface of galvanised sheet was surface-treated using the method according to the invention by treatment with atmospheric-pressure ambient air-generated plasma at a power density of 10 W/cm², exposure time of 3 s, and sample distance of 0.3 mm from the surface of the electrodes. Subsequently, the surfaces of both samples were coated with a layer of γ-APS silane by submerging into a 4% solution of γ-APS in 90.5% of ethanol and 5.5% of deionised water. Silane-coated samples were submerged in a 0.01 M NaCl solution with the temperature of 20° C. After two days of exposure in the NaCl solution, the sample cleaned using the standard method showed obvious surface corrosion while the surface of the plasma-treated sample remained unaffected. The results indicate that the method of treatment according to the invention improved the quality of galvanised steel surface coating with a silane protective layer.

### Example 10

A substrate of monocrystalline silicon was coated with a Pt layer using vacuum deposition as the bottom electrode. Subsequently, the Pt layer was coated using the method of metal organic chemical vapour deposition (MOCVD) at 420° C. with a 15 nm layer of BaSrTiO₃. The layer so deposited contained a substantial amount of carbon-based impurities, which resulted in a significant leakage current when such layer was used, following the deposition of another Pt layer, as a dielectric in a microelectric capacitor. The BaSrTiO₃ layer thus prepared was treated using the method according to the present invention by a 10 s exposure to O₂ plasma at a pressure of 0.2 bar, a power density of 5 W/cm², and a distance from the surface of the electrode system of 0.5 mm. Such treatment resulted in a reduction of the leakage current value by nearly two orders of magnitude.

### Example 11

As determined by the XPS method, the surface of a silver foil exposed to ambient air for a long period of time was covered with a dark layer of Ag₂S. Such surface was treated using the method and apparatus according to the present invention by a 20 s exposure to atmospheric-pressure H₂ plasma at a power density of 10 W/cm² and a distance from the surface of the electrode system of 0.5 mm. As determined by a XPS measurement, the Ag surface was completely rid of the Ag₂S layer following such exposure.

### Example 12

Silicon wafer for the manufacture of solar cells coated with an 80 nm thick layer of silicon nitride. SiNₓ-coated wafer surface had insufficient adhesion to the silver-based paste applied on the surface to form electric contacts. To improve the adhesion, the SiNₓ surface was treated with atmospheric-pressure ambient air-generated plasma using the apparatus according to the invention at a power density of 10 W/cm², exposure time of 3 s, and sample distance of 0.05 mm from the surface of the electrodes. After plasma treatment, the SiNₓ surface was covered with Ag electrodes using silver paste screen-printing and subsequent thermal treatment. Compared to plasma-untreated SiNₓ, a significant improvement of Ag electrode adhesion was found.

### Example 13

A GaN layer was prepared on a sapphire substrate using the CVPD method and doped with Mg atoms yielding a p-type semiconductor. The samples were subsequently treated using the method according to the present invention by a 10 s exposure to O₂ plasma at a pressure of 0.2 bar, a power density of 5 W/cm², and a distance from the surface of the electrode system of 1 mm. Using magnetron sputtering, Ti/Al electrodes were then created on samples thus treated. The electrode contact resistance with the surface of plasma-treated samples was 3.10⁻⁴ Ohm/cm, which is a value one to two orders of magnitude lower than that of the contact resistance without plasma activation.

### Example 14

The surface of a silicon wafer following the removal of the natural oxide layer was activated using the method according to the present invention by a 10 s exposure to N₂ plasma at a pressure of 0.2 bar, a power density of 5 W/cm², and a distance from the surface of the electrode system of 0.5 mm. Subsequently, the surface so activated was coated with a layer of TiN using the CVD method. Compared to plasma-untreated surface, an about 250% increase of adhesion between the Si wafer surface and the deposited layer of TiN was found.

### LIST OF THE REFERENCE SYMBOLS USED

1—electrode system
2—system of electrically conductive electrodes
3—system of electrically conductive electrodes
4—dielectric body
5—metal or metalloid, metal or metalloid oxide, metal nitride or metalloid nitride
6—electric plasma layer
7—auxiliary electrode structure

1. An apparatus for surface treatment of metals and metalloids, metal oxides and metalloid oxides, and metal nitrides and metalloid nitrides using the action of electric plasma characterised in that it includes the electrode system (1) comprising systems of electrically conductive electrodes (2) and (3) that are situated inside of the dielectric body (4) at a minimum relative distance of electrodes (2) and (3) less than 2 mm and more than 0.05 mm, located on the same side of the plasma-treated surface (5), so that the diffuse electric plasma layer (6) is generated on the part of the dielectric body surface (4), preferably above the surface of the electrically conductive electrodes (2) and (3), whereby a significant portion of the electric field lines flux, which is larger than 50% of the total electric field lines flux flowing between the electrodes (2) and (3), is not intersecting the surface of the plasma-treated material (5) that is in contact with plasma (6), the distance of the part of the dielectric body surface (4), on which plasma is generated, from the treated surface (5) is less than 1 mm, and where the plasma layer (6) is not in contact with the electrically conductive electrodes (2) and (3).

2. The apparatus according to claim 1, wherein the voltage of a frequency from 50 Hz to 1 MHz is applied between the electrodes (2) and (3) of the electrode system.

3. The apparatus according to claim 1, wherein the voltage of a magnitude from 0.5 kV to 100 kV is applied between the electrodes (2) and (3) of the electrode system.

4. The apparatus according to claim 1, wherein the apparatus contains the auxiliary electrode structure (7) that is situated inside the dielectric body (4), the structure being part of the electrode system (1) and being at a potential different from that of the electrodes (2) and (3).

5. The apparatus according to claim 1, wherein the dielectric body (4) surface, where the plasma layer (6) is generated, is situated in a working gas with the gas pressure from 1 kPa to 500 kPa.

6. The apparatus according to claim 1, wherein the surface of the plasma-treated material (5) is moving relative to the surface of the dielectric body (4), on which the plasma layer (6) is generated, at a minimum distance of less than 1 mm.

7. A method for treatment of the surface of metals and metalloids, metal oxides and metalloid oxides, and metal nitrides and metalloid nitrides using the action of electric plasma, characterised in that the surface of metals and metalloids, metal oxides and metalloid oxides, and metal nitrides and metalloid nitrides is affected by electric plasma generated using systems of electrically conductive electrodes situated inside of a dielectric body on the same side of the metals and metalloids, metal oxides and metalloid oxides, and metal nitrides and metalloid nitrides, whereby a significant portion of the electric field lines flux, which is larger than 50% of the total electric field lines flux flowing between the electrodes, is not intersecting the surface of the plasma-treated material, where the electric plasma layer is generated on the part of this dielectric body's surface without contact with the electrically conductive electrodes, and where the minimum distance between the portion of the dielectric body surface coated with the plasma layer and the surface of metals and metalloids, metal oxides and metalloid oxides, and metal nitrides and metalloid nitrides is less than 1 mm.

8. A method for treatment of the surface of metals and metalloids, metal oxides and metalloid oxides, and metal nitrides and metalloid nitrides using the action of electric plasma, characterised in that a water containing solution, water containing suspension, or water containing emulsion is deposited on the surface treated according to claim 7 in the form of an aerosol, electrically charged aerosol, foam, by printing or painting.

9. A method for treatment of the surface of metals and metalloids, metal oxides and metalloid oxides, and metal nitrides and metalloid nitrides using the action of electric plasma, characterised in that the surface treated according to claim 7 is further subjected to the action of gaseous environment.

10. A method for treatment of the surface of metals and metalloids, metal oxides and metalloid oxides, and metal nitrides and metalloid nitrides using the action of electric plasma, characterised in that the surface treated according to claim 7 is subsequently coated with a layer of another material using extrusion, lamination, printing, painting, spraying, or electrostatically using a powder.

11. A method for treatment of the surface of metals and metalloids, metal oxides and metalloid oxides, and metal nitrides and metalloid nitrides using the action of electric plasma, characterised in that the surface treated according to claim 7 is subsequently brought in contact with another surface treated according to the method of claim 7.

12. A method for treatment of the surface of metals and metalloids, metal oxides and metalloid oxides, and metal nitrides and metalloid nitrides using the action of electric plasma, characterised in that the surface treated according to claim 7 is subsequently brought in contact with the surface of another solid material.
